(19) United States
(12) Patent Application Publication
(10) Pub. No.: US 2009/0323235 A1
(43) Pub. Date: Dec. 31, 2009

(54) High voltage compliant apparatus for semiconductor fabrication process charging protection

(76) Inventors: Sangwoo Pae, Beaverton, OR (US); Jeff Jones, Beaverton, OR (US); Greg Taylor, Portland, OR (US); Paul Packan, Beaverton, OR (US); Bruce Woolery, Sherwood, OR (US); Jeff Hicks, Banks, OR (US)

Correspondence Address: INTEL CORPORATION;c/o CPA Global, P.O. BOX 52050, MINNEAPOLIS, MN, 55402, US

(21) Appl. No.: 12/215,986

(22) Filed: Jun. 30, 2008

(51) Int. Cl. H02H 9/00; H05K 13/04

(52) U.S. Cl. 361/56; 29/729

(57) ABSTRACT

In some embodiments, semiconductor fabrication process charging protection is provided by coupling a first diode protection device to a high voltage node and coupling a second diode protection device to the first diode protection device at a second node. Other embodiments are described and claimed.

### TECHNICAL FIELD

Embodiments related generally to semiconductor manufacturing, and to semiconductor devices and methods of fabricating a semiconductor device.

### BACKGROUND

In semiconductor manufacturing bulk substrate technology, it is important to prevent in-fab plasma process charging damage on high antenna ratio nodes. This may be accomplished by adding diodes and/or gate-diode transistors. However, the present inventors have identified that it would be beneficial to provide adequate fab in process charging protection while being high-voltage compliant in order to meet reliability voltage requirements of the technology.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a system according to some embodiments of the inventions.

FIG. 2 illustrates a system according to some embodiments of the inventions.

FIG. 3 Shows a current-voltage (I-V) curve for an embodiment of the inventions.

FIG. 4 illustrates the voltage division happening in an embodiment of the inventions.

### DETAILED DESCRIPTION

Some embodiments of the inventions relate to a high voltage compliant apparatus for semiconductor fabrication process charging protection.

In some embodiments, semiconductor fabrication process charging protection is provided by coupling a first diode protection device to a high voltage node and coupling a second diode protection device to the first diode protection device at a second node.

In some embodiments a diode protection device is coupled to a high voltage node used in a semiconductor fabrication process, a voltage drop across the diode protection device is reduced, and semiconductor fabrication process charging protection is performed using the diode protection device.

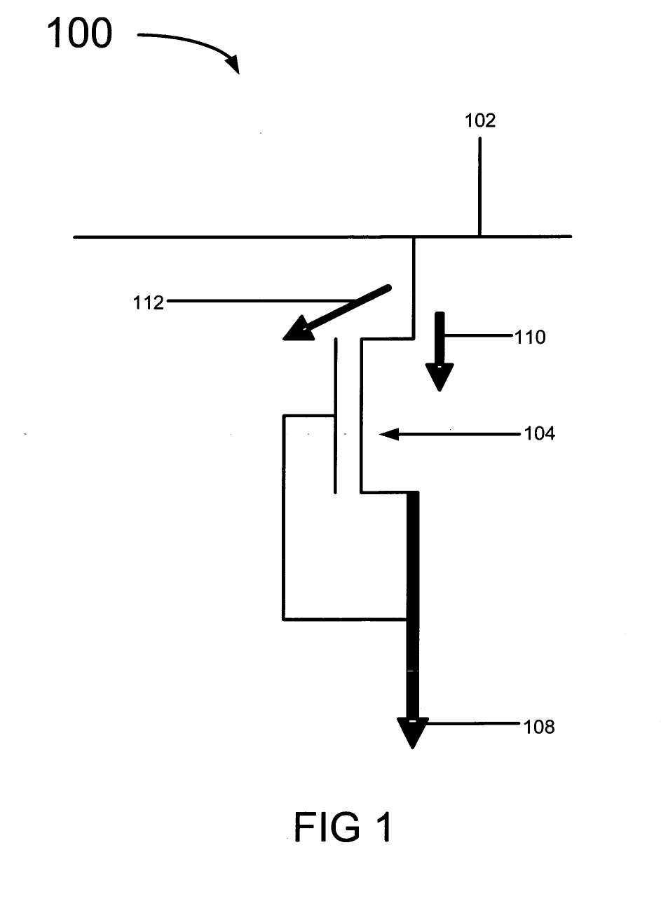

FIG. 1 illustrates a prior art system 100 according to some embodiments. In some embodiments system 100 includes a high voltage node 102 (for example, a high voltage node with a large antenna), a transistor 104, and a low voltage node 108. In some embodiments, transistor 104 is an NMOS (n-channel Metal Oxide Semiconductor) transistor. In this configuration, transistor 104 acts as a gated diode protection device. During fabrication the leakage of this gated diode protection device bleeds charge from the protected high voltage node to the silicon substrate, preventing the buildup of a large voltage potential on this node. In the absence of such protection, enough voltage can build up to damage the gate oxides of transistors who's gates are tied to the signal node. During normal operation, the leakage of the gated diode protection device is small enough to be inconsequential. Note that the voltages that can build up on unprotected nodes during processing are much higher than the voltages that appear on so called “high voltage” nodes during normal operation of the chip. The likelihood of a severe charge buildup is measured by the ratio of metal area for a single process layer to the gate area connected to the metal, the “antenna ratio”.

In some embodiments, the drain of transistor 104 is coupled to the high voltage node 102. In some embodiments the gate of transistor 104 and/or source of transistor 104 is/are coupled to the lower voltage node 108. In some embodiments, FIG. 1 illustrates a transistor, a circuit, an apparatus, and/or a system used for semiconductor fabrication (and/or in-fab) process charging protection.

In FIG. 1, arrow 110 is used to illustrate a junction leakage current. In some embodiments, the junction leakage current is very high due to a large voltage drop across the drain-to-bulk (Vdb) and the drain-to-source (Vds) regions of transistor 104. This high junction leakage current can potentially cause problems with circuit functionality as well as a large increase in the overall power requirements of a semiconductor chip if a large number of transistors 104 are instantiated on a single signal.

In FIG. 1, arrow 112 is used to illustrate a large voltage drop across the drain-to-gate (Vdg) region of transistor 104. A large voltage drop across Vdg can result in reliability issues due to a gate oxide breakdown. For example, on some high voltage signals (102) the absolute value of Vdg (or |Vdg|) is much greater than a technology specified and/or allowed maximum voltage (or Vmax) for gate oxide reliability considerations.

In some embodiments, diode protection devices, gated diode protection devices and/or junction diode protection devices (for example, transistors and/or diodes) are used to provide protection of a high antenna ratio node for semiconductor fabrication induced process charging damage. NMOS diffusion may be used in conjunction with a substrate tap to assist current paths for plasma charge and to provide protection on active circuitry on a node with high antenna ratios. In some embodiments, the transistor has, for example, a gate tied to source and/or substrate taps.

In some embodiments, a transistor connected to a high voltage sees a high voltage drop between a gate and a drain of the transistor, causing reliability risk over the lifetime of the transistor. The reliability risk is gate oxide breakdown, and as a result, a high risk for circuit shorts. Therefore, in some embodiments, a circuit is implemented in which a diode protection device (for example, a gated diode protection device, a junction diode protection device, a high voltage compliant transistor, an NMOS transistor, etc.) provides process charging protection while maintaining compliancy with high voltage requirements of the process. In this manner, the risk of potential reliability concerns is dramatically reduced and/or eliminated.

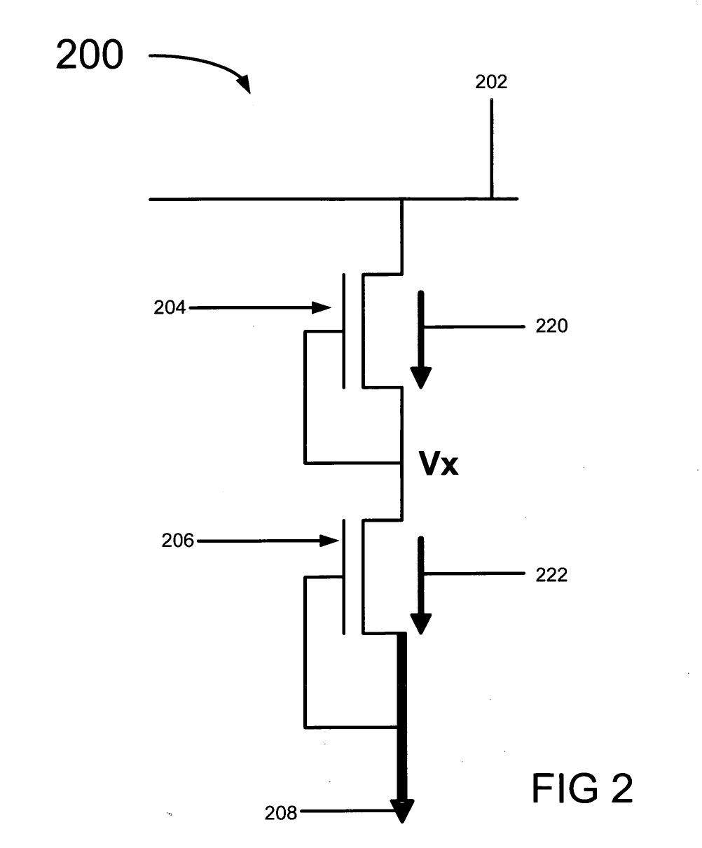

FIG. 2 illustrates a system 200 according to some embodiments. In some embodiments system 200 includes a high voltage node 202 (for example, a high voltage node with a large antenna ratio), a transistor 204, a transistor 206, and a low voltage node 208. In some embodiments, transistor 204 and/or transistor 206 is/are an NMOS (n-channel Metal Oxide Semiconductor) transistor. Note that in this case it is the voltage during normal operation of the chip that causes node 202 to be considered a high voltage node. In particular, node 202 operates at a voltage greater than can be reliably maintained across a single transistor Vgd.

In some embodiments, a drain of transistor 204 is coupled to the high voltage node 202. In some embodiments a gate of transistor 204 and/or a source of transistor 204 is/are coupled to a voltage node Vx. In some embodiments, a drain of transistor 206 is coupled to the voltage node Vx and/or to the gate and/or source of transistor 204. In some embodiments, a gate of transistor 206 and/or a source of transistor 206 is/are coupled to the lower voltage node 208. In some embodiments, FIG. 2 illustrates transistors, a circuit, an apparatus, and/or a system used for semiconductor fabrication (and/or in-fab) process charging protection.

In some embodiments, FIG. 2 illustrates two stacked transistors 204 and 206 (for example, two stacked NMOS transistors). In some embodiments, the voltage drop across each transistor is roughly cut in half relative to the transistor illustrated in FIG. 1, thereby addressing gate oxide reliability concerns. The voltage node Vx of FIG. 2 is approximately one half of the voltage at the high voltage node 202. Similarly, in some embodiments, the voltage Vx of FIG. 2 is approximately one half of the voltage drop Vdg across the drain-gate regions of transistor 104 of FIG. 1. In some embodiments, junction leakage currents illustrated by arrows 220 and 222 in FIG. 2 are significantly reduced compared with the junction leakage current illustrated by arrow 110 in FIG. 1. In some embodiments, the junction leakage currents illustrated by arrows 220 and 222 in FIG. 2 are significantly reduced due to lower drain-source voltages (Vds) per given transistor, thus reducing power concerns.

Although FIG. 2 illustrates two transistors, it is noted that in some embodiments, any number of transistors greater than two may be stacked in a similar arrangement.

In some embodiments, FIG. 2 illustrates a high voltage compliant in-fab process charge protection transistor (and/or transistors) using a stacked transistor arrangement. In some embodiments, FIG. 2 illustrates a circuit, an apparatus, and/or a system in which one or more high voltage compliant transistors (for example, one or more NMOS transistors) provide process charging protection while maintaining compliancy with high voltage requirements of the process, thus reducing and/or eliminating potential reliability concerns.

In some embodiments, stacked transistors (for example, stacked NMOS transistors) are used to avoid a large potential drop across any one transistor, thereby satisfying gate reliability requirements while providing process charging protection. In some embodiments, a stacked structure allows a voltage drop that is one half of the high voltage node in order to avoid violating gate oxide reliability limitations.

In some embodiments, a stacked structure is used so that a total current at a high voltage node is much smaller than that in a single non-high voltage compliant transistor implementation. In the single transistor implementation, a high drain-to-gate voltage drop Vdg causes reliability concerns related to the much larger value of Vdg than the technology specified and/or allowed maximum voltage value Vmax.

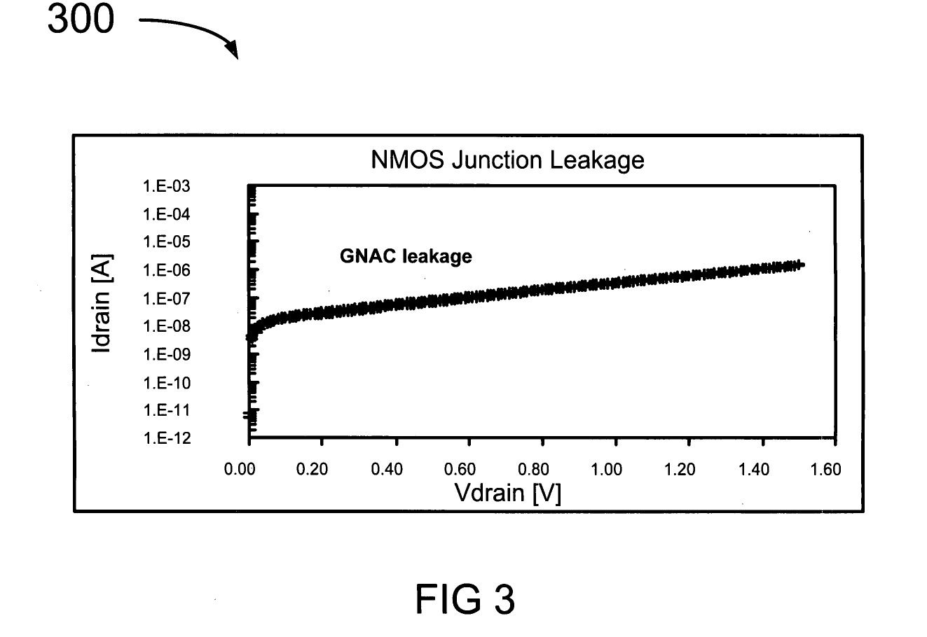

FIG. 3 illustrates a diagram 300 according to some embodiments. In some embodiments, diagram 300 illustrates NMOS junction leakage by comparing drain voltage (Vd) with drain current (Idrain). In some embodiments, diagram 300 illustrates measurement results of a transistor showing an efficient current discharge ability (that is, large leakage in the ˜uA range). In some embodiments, similar levels of leakage will occur (for example, in some embodiments, within about ˜4×). In some embodiments, FIG. 3 illustrates how good process charging protection may be maintained while being compliant with high voltage reliability specifications.

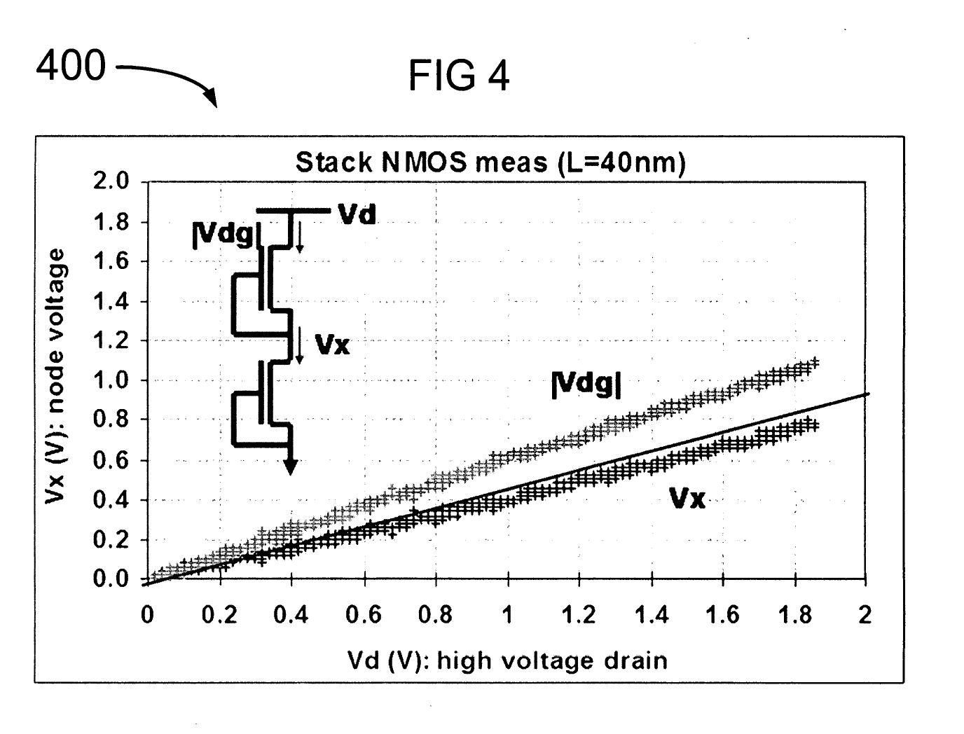

FIG. 4 illustrates a diagram 400 according to some embodiments. In some embodiments, diagram 400 illustrates a comparison of node voltage Vx (for example, node voltage Vx illustrated in FIG. 2) with a high drain voltage Vd (for example, a voltage at high voltage node 202 illustrated in FIG. 2). In some embodiments, diagram 400 illustrates measured voltage characteristics of a stacked NMOS transistor in which a voltage drop on the node Vx is roughly one half of the high voltage node Vd. As illustrated in FIG. 4, an arrangement according to some embodiments (for example, as illustrated in FIG. 2) allows all the voltages that the gate oxide sees will be well within specified and/or allowed ranges (for example, within the reliability Vmax specification).

In some embodiments, a single oxide process is used. In some embodiments, a high voltage compliant transistor (and/or transistors) provides process charging protection, and is compliant with high voltage requirements of the process. In some embodiments, adequate fabrication in process charging protection is provided while maintaining high voltage compliancy in order to meet reliability requirements of the technology. In some embodiments, there is no sacrifice in discharge capability while still having the capability of use with a high voltage power supply (and/or high voltage ratio antenna nodes).

As discussed above, single transistor implementations suffer from gate reliability and large leakage current, resulting in more power consumption by the product. In some embodiments, a stacked arrangement is used in which diode protection devices are stacked, resulting in safer and better reliability as well as lower leakage current.

Although some embodiments have been described herein as using transistors and/or NMOS transistors, according to some embodiments these particular implementations may not be required, and any type of diode protection device may be used. For example, a diode protection device such as a gated diode protection device (and/or Gated Node Area Charging device or GNAC), a junction diode protection device (and/or a Node Area Charging device or NAC), a transistor, and/or an NMOS transistor may be used in some embodiments. In some embodiments using a junction diode protection device, for example, transistor diffusion may be used as the diode (since it's essentially an N+ to P diode). In some embodiments using a junction diode protection device simple use of an N+ to P diffusion diode may be implemented. In some embodiments using a gated diode protection device, both junction leakage Vdb (drain-to-bulk) as well as off-state leakage Vds (drain-to-source) contribute to the total leakage current from the high voltage node (or nodes). In some embodiments using a junction diode protection device only junction leakage plays a role. In some embodiments, a gated diode protection device may be used. In some embodiments, a junction diode protection device may be used (for example, in some embodiments, where the source of a last stack transistor is not at low potential).

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. An apparatus to provide semiconductor fabrication process charging protection, the apparatus comprising:
a first diode protection device coupled to a high voltage node; and
a second diode protection device coupled to the first diode protection device at a second node.

2. The apparatus of claim 1, wherein the first diode protection device is a gated diode protection device and the second diode protection device is a gated diode protection device.

3. The apparatus of claim 1, wherein the first diode protection device is a junction diode protection device and the second diode protection device is a junction diode protection device.

4. The apparatus of claim 1, wherein the first diode protection device is a transistor and the second diode protection device is a transistor.

5. The apparatus of claim 1, wherein the high voltage node is a high antenna ratio node.

6. The apparatus of claim 1, wherein the second node coupling the first and second diode protection devices has a voltage that is a fraction of the voltage of the high voltage node

7. The apparatus of claim 4, wherein the first transistor and the second transistor are NMOS transistors.

8. The apparatus of claim 1, further comprising a third diode protection device coupled to the second diode protection device at a third node having a voltage that is a fraction of the voltage of the second node coupling the first and second diode protection devices.

9. The apparatus of claim 4, the first transistor including a drain coupled to the high voltage node, and a gate and a source each coupled to the second node coupling the first and second transistors.

10. The apparatus of claim 9, wherein the second transistor includes a drain coupled to the gate and the source of the first transistor, and to the second node coupling the first and second transistors, and wherein the second transistor includes a gate and a source coupled to each other.

11. The apparatus of claim 10, wherein the gate and the source of the second transistor are each coupled to a low voltage node.

12. A method comprising:
coupling a diode protection device to a high voltage node used in a semiconductor fabrication process; and
reducing a voltage drop across the diode protection device;
providing semiconductor fabrication process charging protection using the diode protection device.

13. The method of claim 12, wherein the diode protection device is a gated diode protection device.

14. The method of claim 12, wherein the diode protection device is a junction diode protection device.

15. The method of claim 12, wherein the diode protection device is a transistor.

16. The method of claim 12, wherein the reducing is performed by coupling a second diode protection device to the diode protection device that is coupled to the high voltage node.

17. The method of claim 12, wherein the reducing is performed by coupling two or more additional diode protection devices in a stacked fashion to the diode protection device that is coupled to the high voltage node.

18. The method of claim 12, wherein the high voltage node is a high antenna ratio node.

19. The method of claim 16, wherein a node coupling the first and second diode protection devices has a voltage that is a fraction of the voltage of the high voltage node

20. The method of claim 16, wherein the first diode protection device and the second diode protection device are NMOS transistors.
